(19) United States
(12) Patent Application Publication
(10) Pub. No.: US 2025/0063797 A1
(43) Pub. Date: Feb. 20, 2025

(54) ISOLATION MODULE FOR BACKSIDE POWER DELIVERY

(71) Applicant: Applied Materials, Inc., Santa Clara, CA (US)

(72) Inventors: Kyoung Ha KIM, Santa Clara, CA (US); Veeraraghavan S. BASKER, Schenectady, NY (US); Byeong Chan LEE, San Jose, CA (US); Andrew YEOH, Portland, OR (US)

(21) Appl. No.: 18/762,053

(22) Filed: Jul. 2, 2024

Related U.S. Application Data
(60) Provisional application No. 63/617,418, filed on Jan. 4, 2024.
(60) Provisional application No. 63/533,352, filed on Aug. 17, 2023.

(51) Int. Cl. H01L 29/417; H01L 21/283; H01L 21/3065; H01L 29/06; H01L 29/423; H01L 29/45; H01L 29/775; H01L 29/786

(52) U.S. Cl. CPC H01L 29/4175; H01L 21/283; H01L 21/3065; H01L 29/456; H01L 29/0673; H01L 29/42392; H01L 29/775; H01L 29/78696

(57) ABSTRACT

A method of forming a portion of a gate-all-around field-effect transistor includes performing a selective deposition process to form selective cap layers at bottoms of contact trenches formed within portions of a substrate isolated by shallow trench isolations (STIs), wherein the contact trenches each interface with an S/D epitaxial (epi) layer with an extension region, performing a substrate angled etch process to etch sidewalls of the contact trenches, enlarging top critical dimension (CD) of the contact trenches, performing a substrate selective removal plasma (SRP) etch process to isotropically etch the substrate within the contact trenches, performing a recess fill process to fill the contact trenches with dielectric layers, performing an inter-layer dielectric (ILD) recess process to partially remove the substrate between the dielectric layers within the contact trenches and form an ILD recess, and performing a substrate isotropic etch process to partially remove the substrate within the ILD recess.

### CROSS-REFERENCE TO RELATED APPLICATIONS

This application claims priority to U.S. Provisional Application Ser. No. 63/533,352 filed Aug. 17, 2023, and U.S. Provisional Application Ser. No. 63/617,418 filed Jan. 4, 2024, each of which is herein incorporated by reference in its entirety.

### BACKGROUND

### Field

Embodiments described herein generally relate to semiconductor device fabrication, and more particularly, to forming an isolation module for backside power delivery.

### Description of the Related Art

Traditionally, chips are constructed with transistors on a front side of a silicon wafer and all interconnects that power them and transmit their data signals built above them, i.e., to deliver power on the front side of a chip. One of the key technologies to enable scaling below 3 nm involves delivering of power on a back side of a chip. This backside power delivery eliminates the need to share interconnect resources between signals and power lines on a front side of the chip as power is moved to the back side of the chip. Backside power delivery further eliminates the need for a power delivery track from lower layer front side interconnects, leading to cost savings. Backside power delivery also allows different metal layers to be optimally fabricated, such as wider lines for an operating voltage V_{dd} and a common ground voltage Vₛₛ, and thinner lines to carry signals.

However, backside power delivery creates new challenges, such as patterning electrical contact features isolated from one another by isolation modules on a backside of a chip within tight spaces without impacting performance of transistors on a front side of the chip.

Therefore, there is a need for methods for overcoming such challenges in backside power delivery.

### SUMMARY

Embodiments of the present disclosure provide a method of forming a portion of a gate-all-around field-effect transistor (GAA FET). The method includes performing a selective deposition process to form selective cap layers at bottoms of contact trenches formed within portions of a substrate isolated by shallow trench isolations (STIs), wherein the contact trenches each interface with an S/D epitaxial (epi) layer with an extension region, performing a substrate angled etch process to etch sidewalls of the contact trenches, enlarging top critical dimension (CD) of the contact trenches, performing a substrate selective removal plasma (SRP) etch process to isotropically etch the substrate within the contact trenches, performing a recess fill process to fill the contact trenches with dielectric layers, performing an inter-layer dielectric (ILD) recess process to partially remove the substrate between the dielectric layers within the contact trenches and form an ILD recess, performing a substrate isotropic etch process to partially remove the substrate within the ILD recess, and performing an ILD formation process to form an ILD within the ILD recess.

Embodiments of the present disclosure also provide a method forming a portion of a gate-all-around field-effect transistor (GAA FET). The method includes performing a selective deposition process to form selective cap layers at bottoms of contact trenches within portions of a substrate isolated by shallow trench isolations (STIs), wherein the contact trenches each interface with an S/D epitaxial (epi) layer with an extension region, performing a substrate angled etch process to etch sidewalls of the contact trenches, enlarging top critical dimension (CD) of the contact trenches, performing a substrate selective removal plasma (SRP) etch process to isotropically etch the substrate within the contact trenches, performing a recess fill process to fill the contact trenches with dielectric layers, performing an inter-layer dielectric (ILD) recess process to partially remove the substrate between the dielectric layers within the contact trenches and form an ILD recess, performing a substrate isotropic etch process to partially remove the substrate within the ILD recess, performing an ILD formation process to form an ILD within the ILD recess, and performing a contact recess process to partially remove the dielectric layer within the contact trenches, performing a contact liner formation process to form an interface at the bottoms of the contact trenches and a contact liner on exposed inner surfaces of the contact trenches, performing a contact metallization process to fill the contact trenches with metal fill material, and performing a contact metal chemical mechanical polishing (CMP) process to remove the over-filled metal fill material and form a metal contact.

Embodiments of the present disclosure further provide a semiconductor structure forming a portion of a gate-all-around field-effect transistor (GAA FET). The semiconductor structure includes channel layers embedded in an inter-layer dielectric (ILD) formed on a substrate, the channel layers extending in a first direction, a metal gate embedded in the ILD, the metal gate extending in the first direction, a source/drain (S/D) epitaxial (epi) layer that electrically connects the channel layers a S/D contact via an extension region and S/D epitaxial layers on both sides of the channel layers, shallow trench isolations (STIs) formed within the substrate, a metal contact and a dielectric layer formed between the STIs, the metal contact and the dielectric layer extending in a second direction orthogonal to the first direction, wherein the metal contact is electrically connected to the S/D epi layer via the extension region, and extension protect layers formed at bottom corners of the ILD interfacing the dielectric layers with the extension region.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 is a schematic top view of a multi-chamber processing system, according to one or more embodiments of the present disclosure.

FIG. 2 is an isometric view of a portion of a semiconductor structure that may form a gate-all-around field-effect transistor (GAA FET), according to one or more embodiments of the present structure.

FIGS. 3A and 3B depict a process flow diagram of a method of forming a portion of a gate-all-around field-effect transistor (GAA FET) according to one embodiment.

FIGS. 4A, 4B, 4C, 4D, 4E, 4F, 4G, 4H, 4I, 4J, 4K, and 4L are isometric views of a portion of a semiconductor structure corresponding to various states of the method of FIGS. 3A and 3B.

FIG. 5 depicts a process flow diagram of a method of forming a portion of a gate-all-around field-effect transistor (GAA FET) according to one embodiment.

FIGS. 6A, 6B, 6C, 6D, 6E, 6F, 6G, and 6H are isometric views of a portion of a semiconductor structure corresponding to various states of the method of FIG. 5.

To facilitate understanding, identical reference numerals have been used, where possible, to designate identical elements that are common to the figures. It is contemplated that elements and features of one embodiment may be beneficially incorporated in other embodiments without further recitation. In the figures and the following description, an orthogonal coordinate system including an X-axis, a Y-axis, and a Z-axis is used. The directions represented by the arrows in the drawings are assumed to be positive directions for convenience. It is contemplated that elements disclosed in some embodiments may be beneficially utilized on other implementations without specific recitation.

### DETAILED DESCRIPTION

The embodiments described herein provide methods for forming a metal contact embedded within an inter-layer dielectric (ILD) on a backside of a chip while protecting extension regions (e.g., doped silicon (Si) or silicon germanium (SiGe)) on a front side of the chip. Since pattering a silicon (Si) wafer from the backside selectively to the extension regions is not possible, extension protect layers (e.g., silicon (Si)) are formed above the extension regions to protect the extension regions from any damage during the etching of the silicon (Si) wafer.

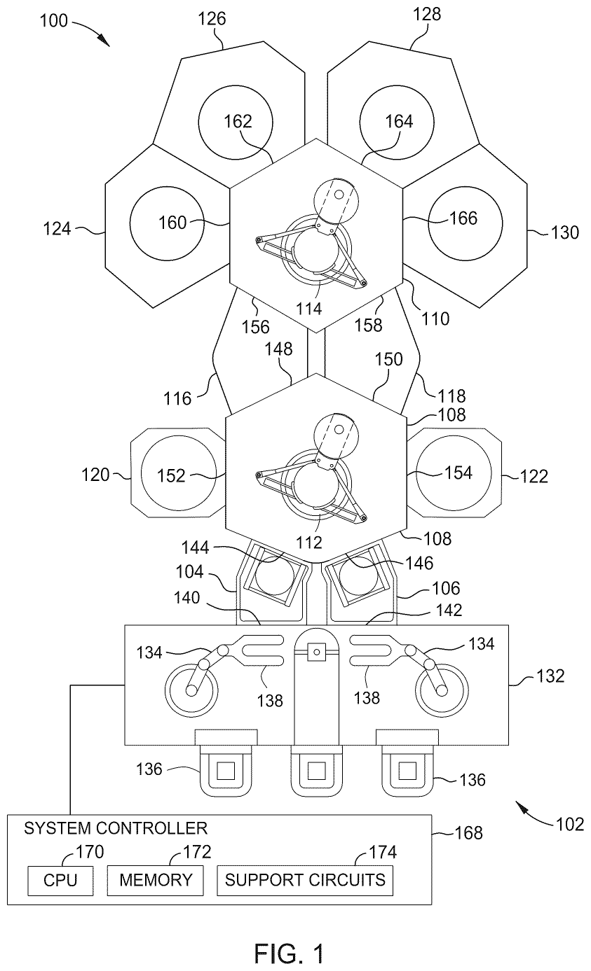

FIG. 1 is a schematic top view of a multi-chamber processing system 100, according to one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment that may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the processing system 100 may provide for an integrated solution for some processing of substrates.

Examples of a processing system that may be suitably modified in accordance with the teachings provided herein include the Endura©, Producer© or Centura© integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152,154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing etch processes, the processing chamber 122 can be capable of performing cleaning processes, the processing chamber 124 can be capable of performing selective removal processes, the processing chamber 126 can be capable of performing chemical vapor deposition (CVD) deposition processes, and the processing chambers 128, 130 can be capable of performing respective epitaxial growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126 may be a W×Z™ chamber available from Applied Materials of Santa Clara, Calif. The processing chamber 128, or 130 may be a Centura™ Epi chamber available from Applied Materials of Santa Clara, Calif.

A system controller 168 is coupled to the processing system 100 for controlling the processing system 100 or components thereof. For example, the system controller 168 may control the operation of the processing system 100 using a direct control of the chambers 104, 106, 108, 110, 116, 118, 120, 122, 124, 126, 128, 130 of the processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

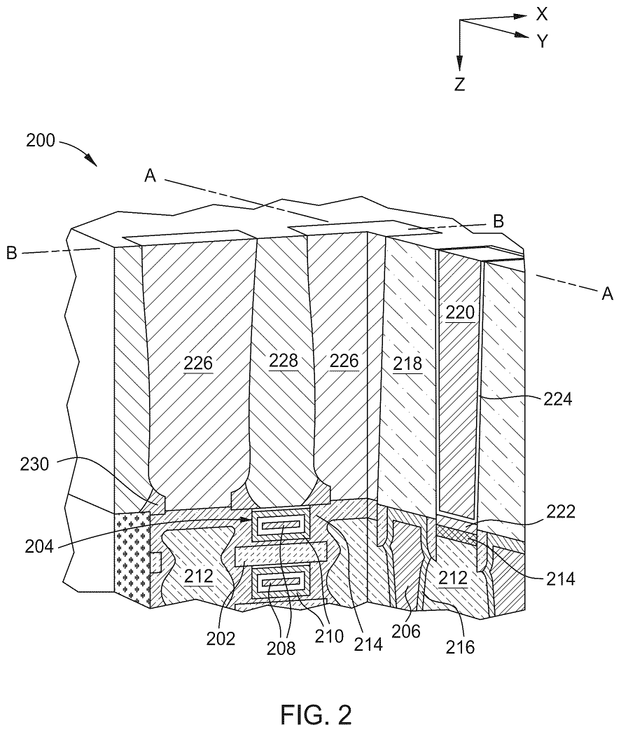

FIG. 2 is an isometric view of a portion of a semiconductor structure 200 that may form a gate-all-around field-effect transistor (GAA FET), according to one or more embodiments of the present structure. In FIG. 2, a cut-out of the semiconductor structure 200 along the YZ plane including the line A-A, and a cut-out of the semiconductor structure 200 along the ZX plane including the line B-B are shown. The semiconductor structure 200 is formed on a substrate and a backside of the semiconductor structure 200 is shown upwards in FIG. 2.

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polycrystalline silicon, doped or undoped silicon wafers and patterned or non-patterned wafers, silicon on insulator (SOI), carbon doped silicon oxides, silicon nitride, doped silicon, germanium, gallium arsenide, glass, or sapphire.

As shown in FIG. 2, the semiconductor structure 200 includes channel layers 202 and replacement-metal-gate (RMG) stacks 204, extending in the Y direction, embedded within a front-side inter-layer dielectric (ILD) 206. Each of the RMG stacks 204 includes a gate metal 208 and a high-k material 210.

The channel layers 202 may be formed of silicon (Si), germanium (Ge), silicon germanium (SiGe), or indium gallium zinc oxide (IGZO). Surfaces of the RMG stacks 204 may be covered by spacers (not shown). The spacers may be formed of dielectric material, such as silicon oxide (SiO₂), silicon oxy-carbide (SiOC), silicon oxy-carbon-nitride (SiOCN), silicon boron carbon nitride (SiBCN), or silicon nitride (Si₃N₄). The front-side ILD 206 may be formed of silicon oxide (SiO₂), silicon oxynitride (SiON), silicon oxy-carbon-nitride (SiOCN), aluminum oxide (Al₂O₃), or any combination thereof. The gate metal 208 may be formed of titanium nitride (TiN), or titanium aluminum carbide (TiAlC), or tungsten (W). The high-k material 210 may be formed of hafnium oxides (HfO₂), hafnium zirconium oxide (HfZrO₂), or aluminum oxide (Al₂O₃).

The semiconductor structure 200 further includes source/drain (S/D) epitaxial (epi) layers 212 that electrically connect the channel layers 202 to an S/D contact (not shown) via an extension region 214. The S/D epi layers 212 are interfaced with the front-side ILD 206 via a contact etch stop layer (CESL) 216.

The S/D contact may be formed of tungsten (W), ruthenium (Ru), molybdenum (Mo), copper (Cu), cobalt (Co), titanium (Ti), nickel (Ni), silver (Ag), gold (Au), iridium (Ir), tantalum (Ta), platinum (Pt), conductive oxides or nitrides thereof, or any combination thereof.

The S/D epi layer 212 may be formed of epitaxially grown silicon germanium (SiGe) with a ratio of germanium (Ge) ranging between 25% and 50%, doped with p-type dopants such as boron (B) or gallium (Ga), with a concentration of between about 10²⁰ cm⁻³ and 5×·10²¹ cm⁻³, or epitaxially grown silicon (Si), doped with n-type dopants, such as phosphorus (P), arsenic (As), or antimony (Sb), with a concentration of between about 10²⁰ cm⁻³ and 5×·10²¹ cm⁻³.

The extension region 214 may be formed of silicon (Si) or silicon germanium (SiGe) with a ratio of germanium (Ge) ranging between 0% and 15%, for example, about 10%, lightly doped with p-type dopants such as boron (B) or gallium (Ga), with a concentration of between about 1×10¹⁸ cm⁻³ and 5×10²⁰ cm⁻³, depending upon the desired conductive characteristic of the extension regions 214.

The semiconductor structure 200 further includes shallow trench isolations (STIs) 218 formed within the substrate. The STIs 218 may be formed of silicon oxide (SiO₂). The S/D epi layer 212 is electrically connected to a metal contact 220, extending in the Z direction, formed between the STIs 218, via an interface 222. The metal contact 220 is connectable to a voltage source (not shown). The metal contact 220 may be each surrounded by a contact liner 224. The S/D epi layers 212 are each interfaced with a dielectric layer 226 via the extension region 214. The RMG stack 204 is interfaced with a backside ILD 228 formed between adjacent dielectric layers 226 in the X direction. At bottom corners of the backside ILDs 228, extension protect layers 230 are formed. The extension protect layers 230 interface the backside ILDs 228 with the underlying extension regions 214 and protect the extension regions 214 from any damage from etch processes during fabrication.

The metal contact 220 may have critical dimensions of about 10 nm and about 40 nm in the XY plane. The metal contact 220 may have a depth in the Z direction of between about 10 nm and 100 nm. The metal contact 220 may be formed of tungsten (W), ruthenium (Ru), molybdenum (Mo), copper (Cu), cobalt (Co), titanium (Ti), nickel (Ni), silver (Ag), gold (Au), iridium (Ir), tantalum (Ta), platinum (Pt), conductive oxides or nitrides thereof, or any combination thereof. The interface 222 may be formed of metal silicide, such as titanium silicide (TiSi, TiSi₂), nickel silicide (NiSi, Ni₂Si), molybdenum silicide (MoSi, MoSi₂), cobalt silicide (CoSi₂), tantalum silicide (TaSi₂), or any combination thereof. The contact liner 224 may be formed of a barrier layer of titanium nitride (TiN), tantalum nitride (TaN), titanium aluminum carbide (TiAlC), or tungsten (W) and a spacer of silicon nitride (Si₃N₄), silicon oxide (SiO₂), silicon oxynitride (SiON), aluminum oxide (Al₂O₃), silicon oxy-carbon-nitride (SiOCN), or any combination thereof. The dielectric layer 226 may be formed of any dielectric material that have etch selectivity to silicon (Si), such as silicon nitride (Si₃N₄), silicon oxide (SiO₂), silicon oxy-carbide (SiOC), silicon oxy-carbon-nitride (SiOCN), or amorphous carbon (a-C).

The backside ILD 228 may be formed of silicon oxide (SiO₂), silicon oxynitride (SiON), aluminum oxide (Al₂O₃), silicon oxy-carbon-nitride (SiOCN), or any combination thereof. The extension protect layers 230 may be formed of silicon (Si).

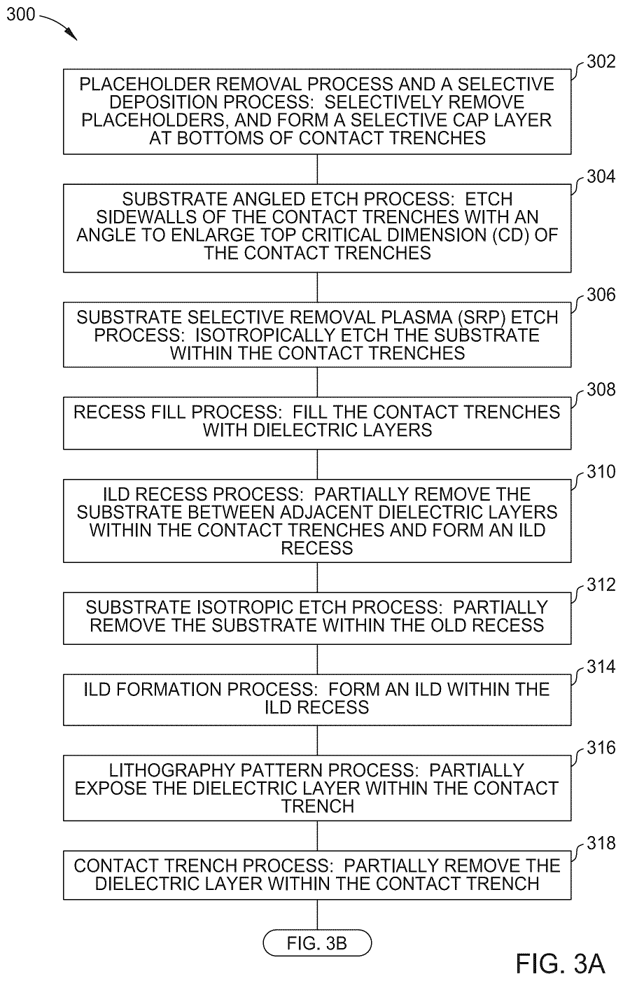

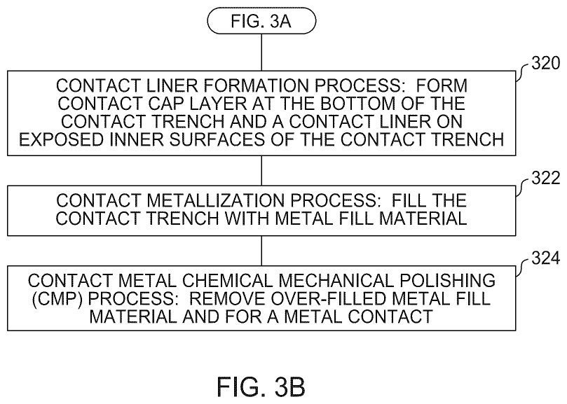

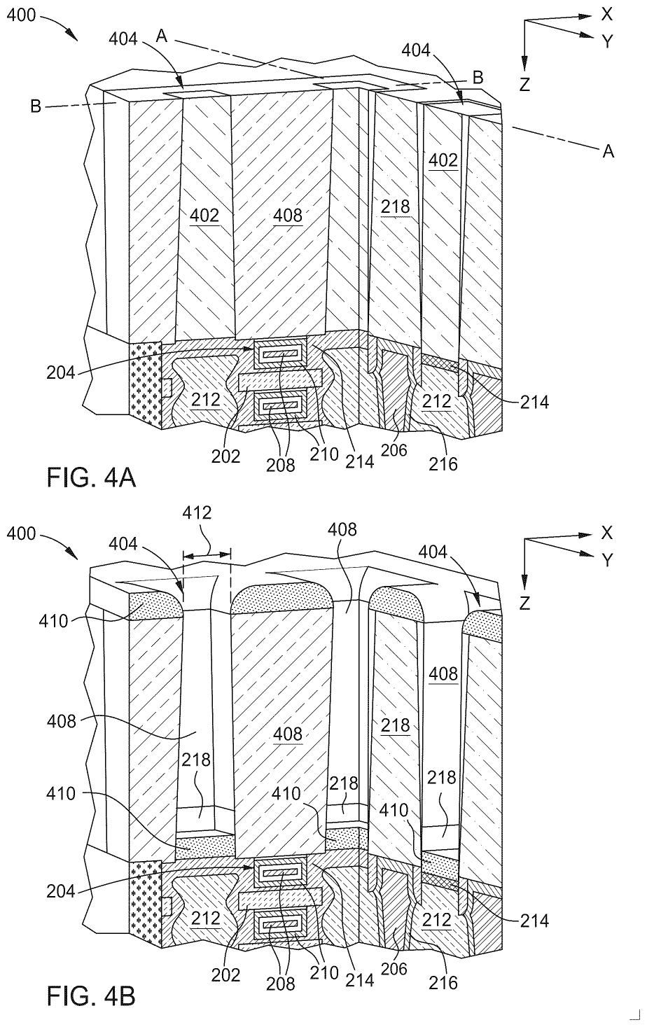

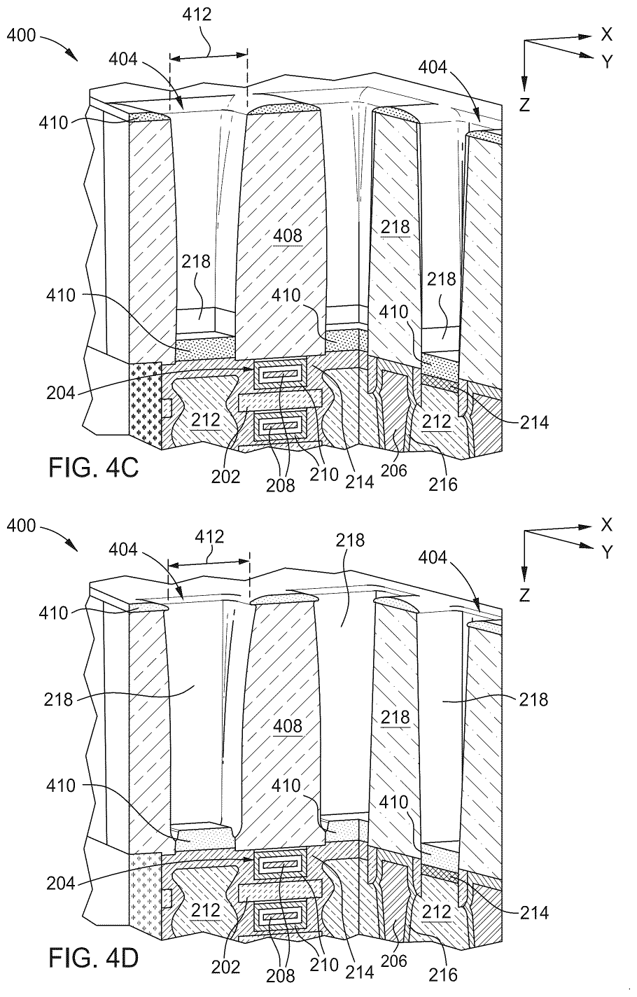

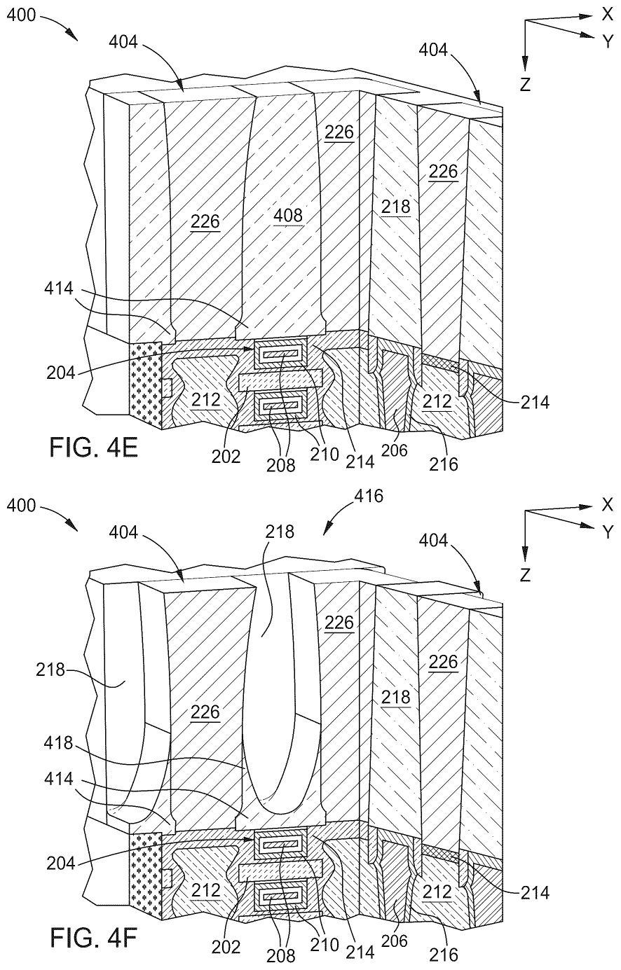

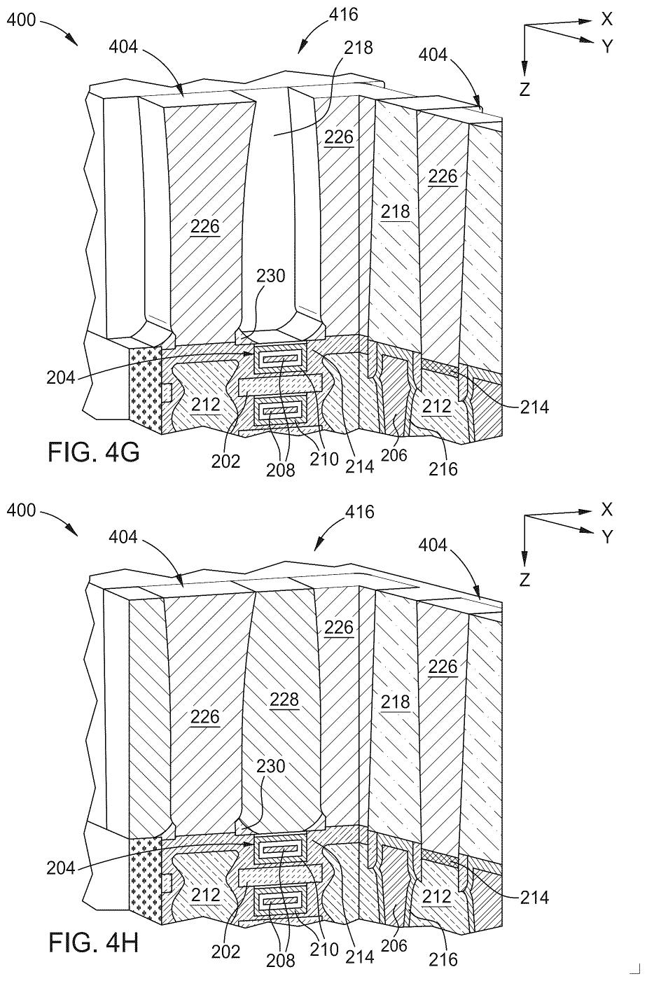

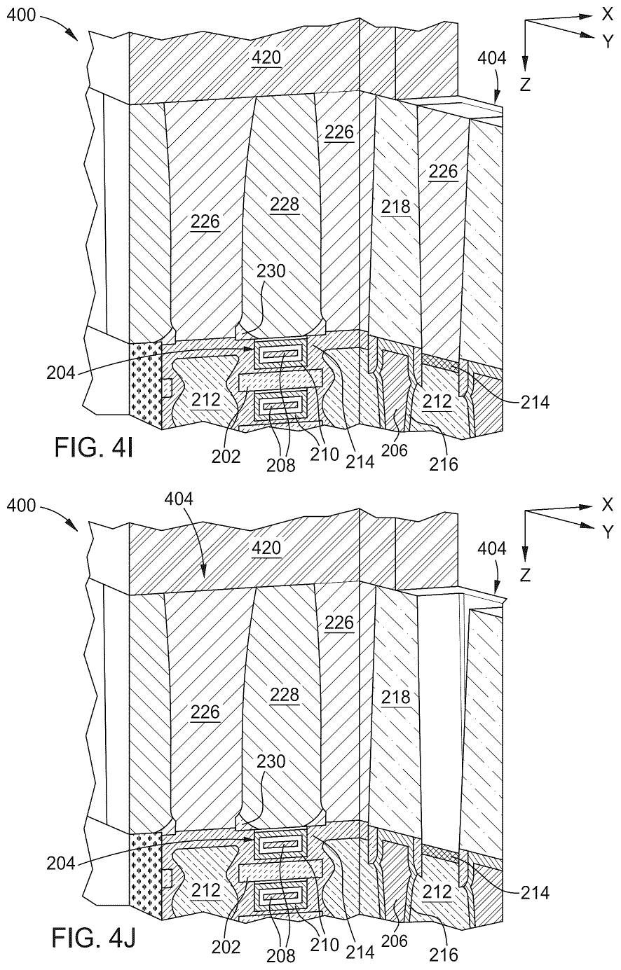

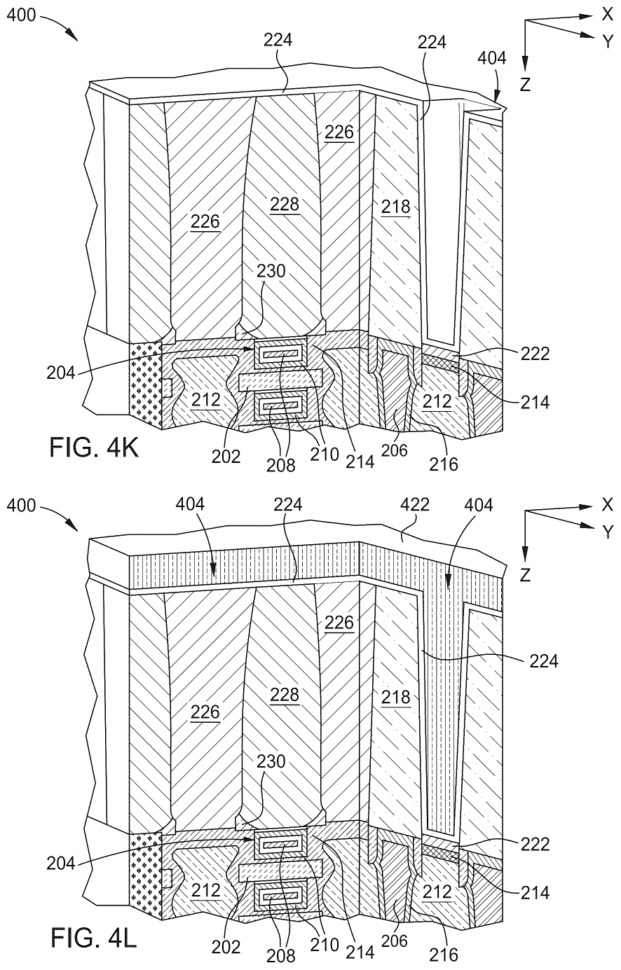

FIGS. 3A and 3B depict a process flow diagram of a method 300 of forming a semiconductor structure 400 that may be the semiconductor structure 200 forming a portion of a gate-all-around field-effect transistor (GAA FET), according to one or more embodiments of the present disclosure. FIGS. 4A, 4B, 4C, 4D, 4E, 4F, 4G, 4H, 4I, 4J, 4K, and 4L are isometric views of a portion of the semiconductor structure 400, with a cut-out of the semiconductor structure 400 along the YZ plane including the line A-A shown in FIG. 4A and a cut-out of the semiconductor structure 400 along the ZX plane including the line B-B shown in FIG. 4A, corresponding to various states of the method 300. A backside of the semiconductor structure 400 is shown upwards. It should be understood that FIGS. 4A, 4B, 4C, 4D, 4E, 4F, 4G, 4H, 4I, 4J, 4K, and 4L illustrate only partial schematic views of the semiconductor structure 400, and the semiconductor structure 400 may contain any number of transistor sections and additional materials having aspects as illustrated in the figures. It should also be noted that although the method illustrated in FIGS. 3A and 3B is described sequentially, other process sequences that include one or more operations that have been omitted and/or added, and/or has been rearranged in another desirable order, fall within the scope of the embodiments of the disclosure provided herein.

As shown in FIG. 4A, the semiconductor structure 400 includes placeholders 402 in contact trenches 404 formed within portions of a substrate 408 isolated by the STIs 218. The placeholders 402 in the contact trenches 404 interface with an S/D epitaxial (epi) layer 212 via an extension region 214.

The placeholder 402 may be formed of material, such as silicon germanium (SiGe), that has etch selectively to the substrate 408 (e.g., silicon (Si)), and the STIs 218 (e.g., (SiO₂).

The method 300 begins with block 302, in which a placeholder removal process and a selective deposition process are performed to selectively remove the placeholders 402, and form a selective cap layer 410 at bottoms of the contact trenches 404, as shown in FIG. 4B. The placeholder removal process may include any appropriate dry anisotropic etch or wet etch process, performed in a processing chamber, such as the processing chamber 120 shown in FIG. 1. The selective deposition process may include any bottom-up gap fill deposition process, performed in a processing chamber, such as the processing chamber 126, 128, or 130 shown in FIG. 1.

The selective cap layer 410 may be formed of any dielectric material that have etch selectivity to silicon (Si), such as silicon nitride (Si₃N₄), silicon oxide (SiO₂), silicon oxy-carbide (SiOC), silicon oxy-carbon-nitride (SiOCN), or amorphous carbon (a-C). The selective cap layers 410 may have a thickness of between about 2 nm and about 50 nm, and act as an etch stop in the isotropic etch process in block 306.

In block 304, a substrate angled etch process is performed to etch sidewalls of the contact trenches 404 with an angle to enlarge top critical dimension (CD) 412 of the contact trenches 404, as shown in FIG. 4C. The substrate angled etch process may include an etch process using a reactive plasma ribbon beam at a desired angle, performed in a process chamber such as Varian VIISta© Raptor DRB© system available from Applied Materials, Inc. located in Santa Clara, Calif, or the processing chamber 120 shown in FIG. 1.

The contact trenches 404 each have a width in the X direction of between about 10 nm and about 500 nm at the bottom and between about 10 nm and about 500 nm at the top of the contact trenches 404 after the angled etch process is performed.

In block 306, a substrate selective removal plasma (SRP) etch process is performed to isotropically etch the substrate 408 within the contact trenches 404, as shown in FIG. 4D. The substrate selective removal plasma (SRP) etch process may be performed in a processing chamber, such as the processing chamber 120 shown in FIG. 1.

Due to the thickness of the selective cap layer 410 and the etch selectivity of the substrate 408 (e.g., silicon (Si)) to the selective cap layer 410 (e.g., silicon nitride (Si₃N₄)), portions 414 of the substrate 408 above the extension regions 214 remain un-etched during the substrate isotropic etch process. The un-etched portions 414 may prevent any etch into the extension regions 214 in the etch process in block 310.

In block 308, a recess fill process is performed to fill the contact trenches 404 with dielectric layers 226, as shown in FIG. 4E. The recess fill process may include any appropriate deposition process, such as chemical vapor deposition (CVD), physical vapor deposition (PVD), or the like performed in a processing chamber, such as the processing chamber 126, 128, or 130 shown in FIG. 1.

The dielectric layers 226 may be formed of any dielectric material that have etch selectivity to silicon (Si), such as silicon nitride (Si₃N₄), silicon oxide (SiO₂), silicon oxy-carbide (SiOC), silicon oxy-carbon-nitride (SiOCN), or amorphous carbon (a-C). Since the contact trenches 404 have angled sidewalls, formed in the substrate angled etch process in block 304, the filled dielectric layer 226 has angled sidewalls having a larger CD at the top than at the bottom.

In block 310, an ILD recess process is performed to partially remove the substrate 408 between adjacent dielectric layers 226 within the contact trenches 404 and form an ILD recess 416, as shown in FIG. 4F. The ILD recess process may include an anisotropic etch process, such as a reactive ion etch process, performed in a processing chamber, such as CENTRIS® SYM3™ etch chamber available from Applied Materials, Inc. of Santa Clara, California, or the processing chamber 120 shown in FIG. 1.

Due to the angled sidewalls of the dielectric layers 226, portions 418 of the substrate 408 at the bottom of the ILD recess 416 remain un-etched during the substrate anisotropic etch process. The un-etched portions 414 of the substrate 408 remain un-etched.

In block 312, a substrate isotropic etch process is performed to partially remove the substrate 408 within the ILD recess 416, as shown in FIG. 4G. The substrate isotropic etch process may include any wet etch process, performed in a processing chamber, such as the processing chamber 120 shown in FIG. 1.

The un-etched portions 414 and 418 of the substrate 408 are partially etched during the substrate isotropic etch process and an extension protect layer 230 remains. The extension protect layer 230 protects underlying extension regions 214 from any damage during the substrate isotropic etch process.

In block 314, an ILD formation process is performed to form a backside ILD 228 within the ILD recess 416, as shown in FIG. 4H.

The backside ILD 228 may be formed of silicon oxide (SiO₂), silicon oxynitride (SiON), aluminum oxide (Al₂O₃), silicon oxy-carbon-nitride (SiOCN) or any combination thereof. The backside of the semiconductor structure 400 may be planarized by a chemical mechanical polishing (CMP) process to remove over-filled material (e.g., silicon oxide (SiO₂)).

In block 316, a lithography pattern process is performed to partially expose the dielectric layer 226 within the contact trenches 404, as shown in FIG. 4I. The lithography pattern process may include a conventional photolithographic process using a patterned photoresist layer 420.

In block 318, a contact recess process is performed to partially remove the dielectric layer 226 within the contact trenches 404, as shown in FIG. 4J. The contact recess process may include any appropriate dry anisotropic etch or wet etch process, performed in a processing chamber, such as the processing chamber 120 shown in FIG. 1. Subsequently the photoresist layer 420 is removed.

In block 320, an interface formation process is performed to form an interface 222 at the bottom of the contact trenches 404 and a contact liner 224 on exposed inner surfaces of the contact trenches 404, as shown in FIG. 4K. The contact liner formation process may include any appropriate deposition process, such as chemical vapor deposition (CVD), physical vapor deposition (PVD), or the like performed in a processing chamber, such as the processing chamber 126, 128, or 130 shown in FIG. 1. The interface 222 may be formed of metal silicide, such as titanium silicide (TiSi, TiSi₂), nickel silicide (NiSi, Ni₂Si), molybdenum silicide (MoSi, MoSi₂), cobalt silicide (CoSi₂), tantalum silicide (TaSi₂), or any combination thereof. The backside ILD 228 may be formed of silicon oxide (SiO₂), silicon oxynitride (SiON), aluminum oxide (Al₂O₃), silicon oxy-carbon-nitride (SiOCN), or any combination thereof. The contact liner 224 may be formed a barrier layer of titanium nitride (TiN), tantalum nitride (TaN), titanium aluminum carbide (TiAlC), or tungsten (W) and of silicon nitride (Si₃N₄), silicon oxide (SiO₂), silicon oxynitride (SiON), aluminum oxide (Al₂O₃), silicon oxy-carbon-nitride (SiOCN), or any combination thereof.

In block 322, a contact metallization process is performed to fill the contact trenches 404 with metal fill material 422, as shown in FIG. 4L. The contact metallization process may include any appropriate deposition process, such as chemical vapor deposition (CVD), physical vapor deposition (PVD), or the like performed in a processing chamber, such as the processing chamber 126, 128, or 130 shown in FIG. 1. The metal fill material 422 may be formed of tungsten (W), ruthenium (Ru), molybdenum (Mo), copper (Cu), cobalt (Co), titanium (Ti), nickel (Ni), silver (Ag), gold (Au), iridium (Ir), tantalum (Ta), platinum (Pt), conductive oxides or nitrides thereof, or any combination thereof.

In block 324, a contact metal chemical mechanical polishing (CMP) process is performed to planarize the backside of the semiconductor structure 400, removing over-filled metal fill material and forming a metal contact 220. The semiconductor structure 400 after the contact metal CMP process may be the semiconductor structure 200 as shown in FIG. 2.

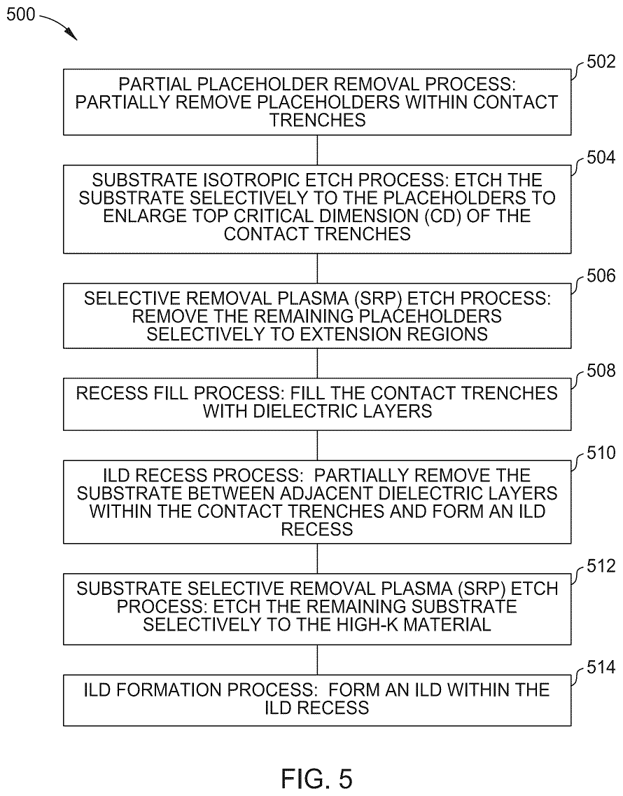

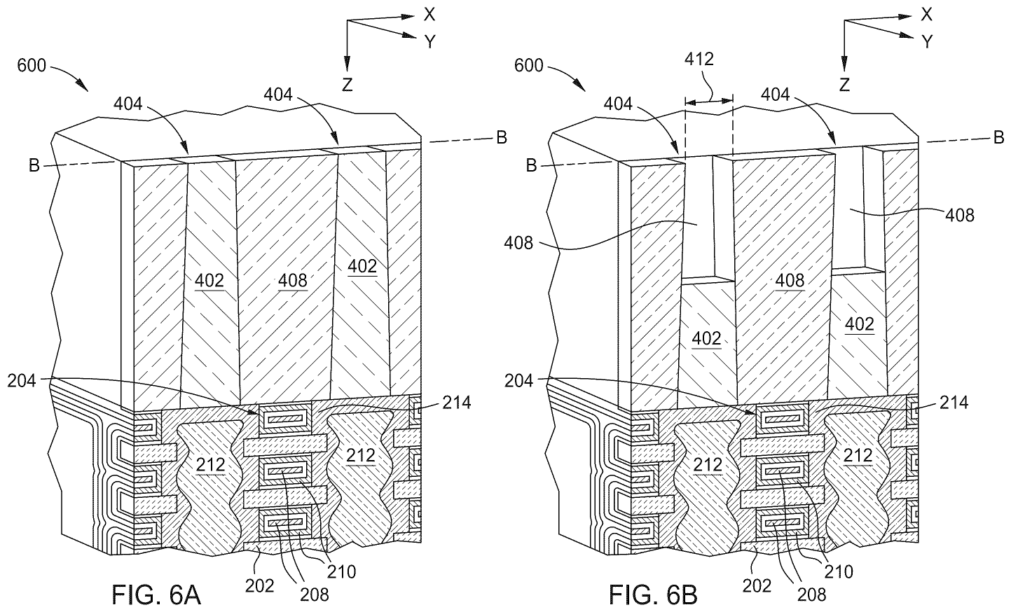

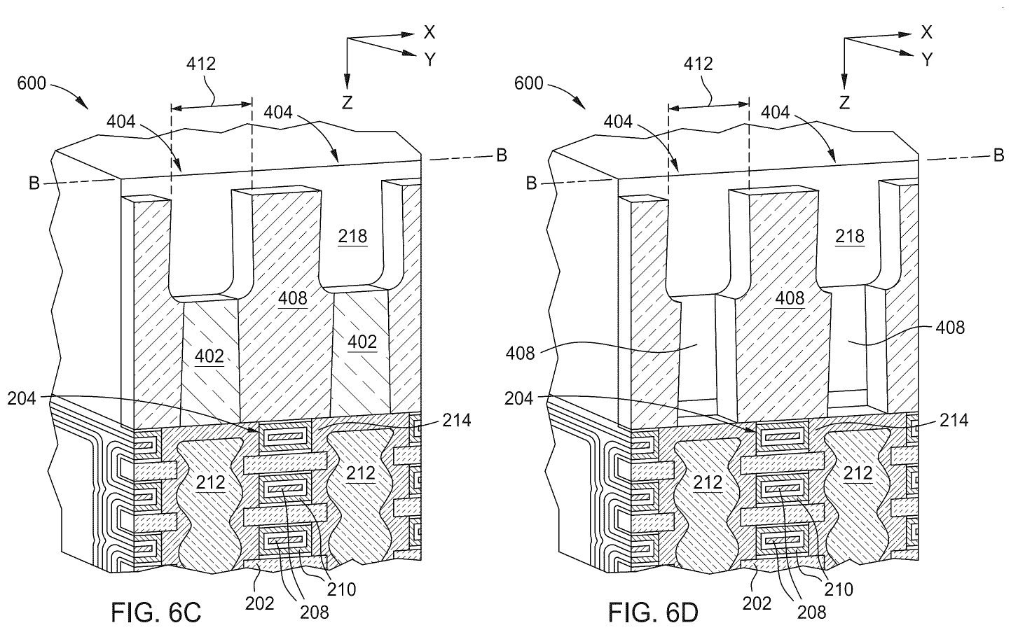

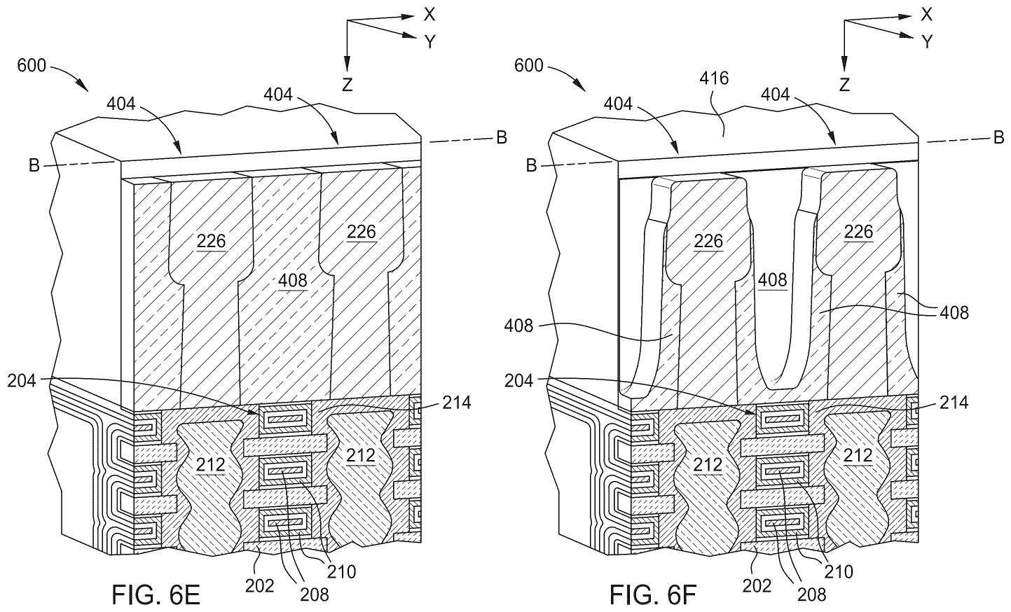

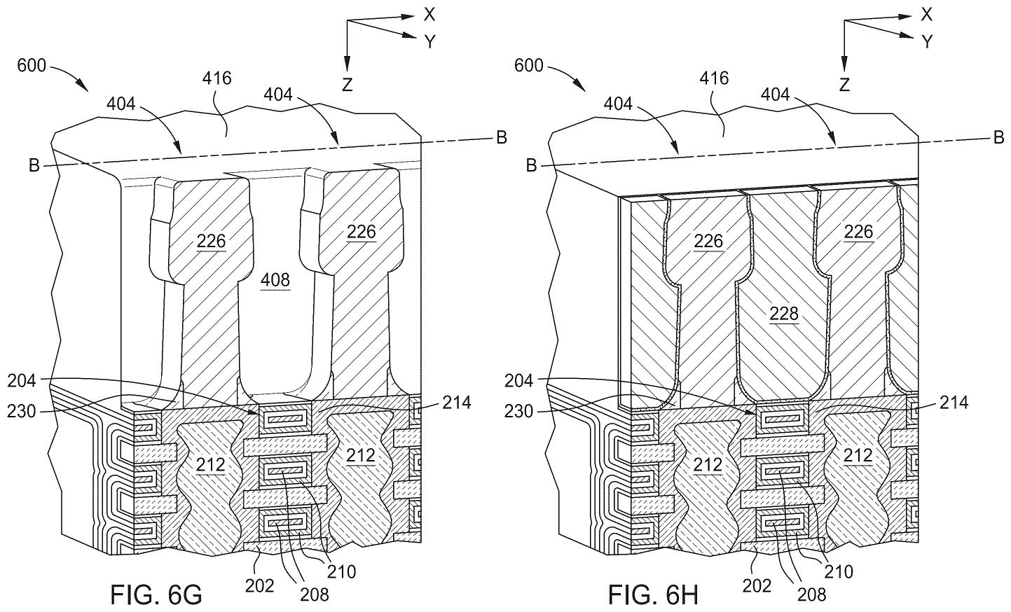

FIG. 5 depicts a process flow diagram of a method 500 of forming a semiconductor structure 600 that may be the semiconductor structure 200 forming a portion of a gate-all-around field-effect transistor (GAA FET), according to one or more embodiments of the present disclosure. FIGS. 6A, 6B, 6C, 6D, 6E, 6F, 6G, and 6H are isometric views of a portion of the semiconductor structure 600, with a cut-out of the semiconductor structure 600 along the ZX plane including the line B-B shown in FIG. 6A, corresponding to various states of the method 500. A backside of the semiconductor structure 600 is shown upwards. It should be understood that FIGS. 6A, 6B, 6C, 6D, 6E, 6F, 6G, and 6H illustrate only partial schematic views of the semiconductor structure 400, and the semiconductor structure 600 may contain any number of transistor sections and additional materials having aspects as illustrated in the figures. It should also be noted that although the method illustrated in FIG. 5 is described sequentially, other process sequences that include one or more operations that have been omitted and/or added, and/or has been rearranged in another desirable order, fall within the scope of the embodiments of the disclosure provided herein.

As shown in FIG. 6A, the semiconductor structure 600 includes placeholders 402 in contact trenches 404 formed within portions of a substrate 408 isolated by STIs 218 (not shown in FIG. 6A). The placeholders 402 in the contact trenches 404 interface with an S/D epitaxial (epi) layer 212 via an extension region 214.

The placeholder 402 may be formed of material, such as silicon germanium (SiGe), that has etch selectively to the substrate 408 (e.g., silicon (Si)), and the STIs 218 (e.g., (SiO₂).

The method 500 begins with block 502, in which a partial placeholder removal process to partially remove the placeholders 402 within the contact trenches 404, as shown in FIG. 6B. The placeholder removal process may include any appropriate dry anisotropic etch or wet etch process, performed in a processing chamber, such as the processing chamber 120 shown in FIG. 1.

In block 504, a substrate isotropic etch process is performed to etch the substrate 408 selectively to the placeholders 402 to enlarge top critical dimension (CD) 412 of the contact trenches 404, as shown in FIG. 6C. The substrate isotropic etch process may include any wet etch process, performed in a processing chamber, such as the processing chamber 120 shown in FIG. 1.

In block 506, a selective removal plasma (SRP) etch process is performed to remove the remaining placeholders 402 selectively to the extension regions 214, as shown in FIG. 6D. The SRP etch process may be performed in a processing chamber, such as the processing chamber 120 shown in FIG. 1.

In block 508, a recess fill process is performed to fill the contact trenches 404 with dielectric layers 226, as shown in FIG. 6E. The recess fill process may include any appropriate deposition process, such as chemical vapor deposition (CVD), physical vapor deposition (PVD), or the like performed in a processing chamber, such as the processing chamber 126, 128, or 130 shown in FIG. 1.

The dielectric layers 226 may be formed of any dielectric material that have etch selectivity to silicon (Si), such as silicon nitride (Si₃N₄), silicon oxide (SiO₂), silicon oxy-carbide (SiOC), silicon oxy-carbon-nitride (SiOCN), or amorphous carbon (a-C). The filled dielectric layer 260 has a larger CD at the top than at the bottom.

The backside of the semiconductor structure 600 may be planarized by a chemical mechanical polishing (CMP) process to remove over-filled material (e.g., dielectric material).

In block 510, an ILD recess process is performed to partially remove the substrate 408 between adjacent dielectric layers 226 within the contact trenches 404 and form an ILD recess 416, as shown in FIG. 6F. The ILD recess process may include an anisotropic etch process, such as a reactive ion etch process, performed in a processing chamber, such as CENTRIS® SYM3™ etch chamber available from Applied Materials, Inc. of Santa Clara, California, or the processing chamber 120 shown in FIG. 1.

In block 512, a substrate selective removal plasma (SRP) etch process is performed to etch the remaining substrate 408 selectively to the high-k material 210, as shown in FIG. 6G. The substrate selective removal plasma (SRP) etch process may be performed in a processing chamber, such as the processing chamber 120 shown in FIG. 1.

During the substrate SRP etch process, a portion 230 of the substrate 408 remains un-etched, and acts as an extension protection layer that protects underlying extension regions 214 from any damage.

In block 514, an ILD formation process is performed to form a backside ILD 228 within the ILD recess 416, as shown in FIG. 6H.

The backside ILD 228 may be formed of silicon oxide (SiO₂), silicon oxynitride (SiON), aluminum oxide (Al₂O₃), silicon oxy-carbon-nitride (SiOCN) or any combination thereof. In some embodiments, a liner 424 formed of silicon nitride (Si₃N₄) is deposited within the ILD recess 416. The backside of the semiconductor structure 400 may be planarized by a chemical mechanical polishing (CMP) process to remove over-filled material (e.g., silicon oxide (SiO₂)).

The embodiments described herein provide methods for forming a metal contact in an inter-layer dielectric (ILD) on a backside of a chip while protecting extension regions (e.g., doped silicon (Si) or silicon germanium (SiGe)) on a front side of the chip. In the methods described herein, extension protect layers (e.g., silicon (Si)) are formed above the extension regions to protect the extension regions from any damage during the etching of the silicon (Si) wafer.

While the foregoing is directed to embodiments of the present disclosure, other and further embodiments of the disclosure may be devised without departing from the basic scope thereof, and the scope thereof is determined by the claims that follow.

1. A method of forming a portion of a gate-all-around field-effect transistor (GAA FET), comprising:
performing a selective deposition process to form selective cap layers at bottoms of contact trenches formed within portions of a substrate isolated by shallow trench isolations (STIs), wherein the contact trenches each interface with an S/D epitaxial (epi) layer with an extension region;
performing a substrate angled etch process to etch sidewalls of the contact trenches, enlarging top critical dimension (CD) of the contact trenches;
performing a substrate selective removal plasma (SRP) etch process to isotropically etch the substrate within the contact trenches;
performing a recess fill process to fill the contact trenches with dielectric layers;
performing an inter-layer dielectric (ILD) recess process to partially remove the substrate between the dielectric layers within the contact trenches and form an ILD recess;
performing a substrate isotropic etch process to partially remove the substrate within the ILD recess; and
performing an ILD formation process to form an ILD within the ILD recess.

2. The method of claim 1, wherein:
the substrate comprises silicon (Si),
the STIs comprise silicon oxide (SiO₂),
the extension region comprises lightly doped silicon (Si) or silicon germanium (SiGe), and
the ILD comprises silicon oxide (SiO₂), silicon oxynitride (SiON), aluminum oxide, or (Al₂O₃).

3. The method of claim 1, wherein the selective cap layers and the dielectric layers each comprise silicon nitride (Si₃N₄), silicon oxide (SiO₂), silicon oxy-carbide (SiOC), silicon oxy-carbon-nitride (SiOCN), or amorphous carbon (a-C).

4. The method of claim 3, wherein the selective cap layers each have a thickness of between 2 nm and 50 nm.

5. The method of claim 1, wherein:
the S/D epi layer comprises epitaxially grown silicon germanium (SiGe) doped with p-type dopants, or epitaxially grown silicon (Si), doped with n-type dopants.

6. The method of claim 1, further comprising:
performing a contact recess process to partially remove the dielectric layers within the contact trenches;
performing a contact liner formation process to form an interface at the bottoms of the contact trenches and a contact liner on exposed inner surfaces of the contact trenches;
performing a contact metallization process to fill the contact trenches with metal fill material; and
performing a contact metal chemical mechanical polishing (CMP) process to remove the over-filled metal fill material and form a metal contact.

7. The method of claim 6, wherein the metal contact comprises tungsten (W), ruthenium (Ru), molybdenum (Mo), copper (Cu), cobalt (Co), titanium (Ti), nickel (Ni), silver (Ag), gold (Au), iridium (Ir), tantalum (Ta), platinum (Pt), conductive oxides or nitrides thereof, or any combination thereof.

8. The method of claim 6, wherein:
the interface comprises titanium silicide (TiSi, TiSi₂), nickel silicide (NiSi, Ni₂Si), molybdenum silicide (MoSi, MoSi₂), cobalt silicide (CoSi₂), tantalum silicide (TaSi₂), or any combination thereof, and
the contact liner comprises a barrier layer of titanium nitride (TiN), tantalum nitride (TaN), titanium aluminum carbide (TiAlC), or tungsten (W) and a spacer of silicon nitride (Si₃N₄), silicon oxide (SiO₂), silicon oxynitride (SiON), aluminum oxide (Al₂O₃), silicon oxy-carbon-nitride (SiOCN), or any combination thereof.

9. A method of forming a portion of a gate-all-around field-effect transistor (GAA FET), comprising:
performing a selective deposition process to form selective cap layers at bottoms of contact trenches within portions of a substrate isolated by shallow trench isolations (STIs), wherein the contact trenches each interface with an S/D epitaxial (epi) layer with an extension region;
performing a substrate angled etch process to etch sidewalls of the contact trenches, enlarging top critical dimension (CD) of the contact trenches;
performing a substrate selective removal plasma (SRP) etch process to isotropically etch the substrate within the contact trenches;
performing a recess fill process to fill the contact trenches with dielectric layers;
performing an inter-layer dielectric (ILD) recess process to partially remove the substrate between the dielectric layers within the contact trenches and form an ILD recess;
performing a substrate isotropic etch process to partially remove the substrate within the ILD recess;
performing an ILD formation process to form an ILD within the ILD recess; and
performing a contact recess process to partially remove the dielectric layer within the contact trenches;
performing a contact liner formation process to form an interface at the bottoms of the contact trenches and a contact liner on exposed inner surfaces of the contact trenches;
performing a contact metallization process to fill the contact trenches with metal fill material; and
performing a contact metal chemical mechanical polishing (CMP) process to remove the over-filled metal fill material and form a metal contact.

10. The method of claim 9, wherein:
the substrate comprises silicon (Si),
the STIs comprise silicon oxide (SiO₂),
the extension region comprises lightly doped silicon (Si) or silicon germanium (SiGe), and
the ILD comprises silicon oxide (SiO₂), silicon oxynitride (SiON), aluminum oxide, or (Al₂O₃).

11. The method of claim 9, wherein the selective cap layers and the dielectric layers each comprise silicon nitride (Si₃N₄), silicon oxide (SiO₂), silicon oxy-carbide (SiOC), silicon oxy-carbon-nitride (SiOCN), or amorphous carbon (a-C).

12. The method of claim 11, wherein the selective cap layers each have a thickness of between 2 nm and 50 nm.

13. The method of claim 9, wherein:
the S/D epi layer comprises epitaxially grown silicon germanium (SiGe) doped with p-type dopants, or epitaxially grown silicon (Si), doped with doped with n-type dopants.

14. The method of claim 9, wherein the metal contact comprises tungsten (W), ruthenium (Ru), molybdenum (Mo), copper (Cu), cobalt (Co), titanium (Ti), nickel (Ni), silver (Ag), gold (Au), iridium (Ir), tantalum (Ta), platinum (Pt), conductive oxides or nitrides thereof, or any combination thereof.

15. The method of claim 9, wherein:
the interface comprises titanium silicide (TiSi, TiSi₂), nickel silicide (NiSi, Ni₂Si), molybdenum silicide (MoSi, MoSi₂), cobalt silicide (CoSi₂), tantalum silicide (TaSi₂), or any combination thereof, and
the contact liner comprises a barrier layer of titanium nitride (TiN), tantalum nitride (TaN), titanium aluminum carbide (TiAlC), or tungsten (W) and a spacer of silicon nitride (Si₃N₄), silicon oxide (SiO₂), silicon oxynitride (SiON), aluminum oxide (Al₂O₃), silicon oxy-carbon-nitride (SiOCN), or any combination thereof.

16. A semiconductor structure forming a portion of a gate-all-around field-effect transistor (GAA FET), comprising:
channel layers embedded in an inter-layer dielectric (ILD) formed on a substrate, the channel layers extending in a first direction;
a metal gate embedded in the ILD, the metal gate extending in the first direction;
a source/drain (S/D) epitaxial (epi) layer that electrically connects the channel layers a S/D contact via an extension region and S/D epitaxial layers on both sides of the channel layers;
shallow trench isolations (STIs) formed within the substrate;
a metal contact and a dielectric layer formed between the STIs, the metal contact and the dielectric layer extending in a second direction orthogonal to the first direction, wherein the metal contact is electrically connected to the S/D epi layer via the extension region; and
extension protect layers formed at bottom corners of the ILD interfacing the dielectric layers with the extension region.

17. The semiconductor structure of claim 16, wherein the extension protect layers comprise silicon (Si).

18. The semiconductor structure of claim 16, wherein:
the channel layers comprise silicon (Si), germanium (Ge), silicon germanium (SiGe), or indium gallium zinc oxide (IGZO), and
the metal gate comprises tungsten (W), ruthenium (Ru), molybdenum (Mo), copper (Cu), cobalt (Co), titanium (Ti), nickel (Ni), silver (Ag), gold (Au), iridium (Ir), tantalum (Ta), platinum (Pt), conductive oxides or nitrides thereof, or any combination thereof.

19. The semiconductor structure of claim 16, wherein:
the STIs comprise silicon oxide (SiO₂),
the extension region comprises lightly doped silicon (Si) or silicon germanium (SiGe), and
the ILD comprises silicon oxide (SiO₂), silicon oxynitride (SiON), aluminum oxide, or (Al₂O₃).

20. The semiconductor structure of claim 16, further comprising:
an interface between the S/D epi layer and the metal contact,
wherein the interface comprises metal silicide, such as titanium silicide (TiSi, TiSi₂), nickel silicide (NiSi, Ni₂Si), molybdenum silicide (MoSi, MoSi₂), cobalt silicide (CoSi₂), tantalum silicide (TaSi₂), or any combination thereof.
